(19) United States
(12) Patent Application Publication
(10) Pub. No.: US 2026/0150718 A1
(43) Pub. Date: May 28, 2026

(54) SEMICONDUCTOR PACKAGE WITH TIN COVERED LEADS

(71) Applicant: TEXAS INSTRUMENTS INCORPORATED, DALLAS, TX (US)

(72) Inventors: Xueqi Yang, Shanghai (CN); Lance Wright, Allen, TX (US); Satyendra Chauhan, Murphy, TX (US); Xuan Mo Li, Chengdu (CN); Pan Li, Shanghai (CN)

(21) Appl. No.: 18/962,009

(22) Filed: Nov. 27, 2024

(51) Int. Cl. H01L 23/498; H01L 21/48; H01L 23/31

(52) U.S. Cl. CPC H10W 70/479; H10W 70/048; H10W 70/66; H10W 74/111; H10W 90/701

(57) ABSTRACT

A semiconductor package includes a die with an embedded circuit. The semiconductor package includes an interconnect with a die pad, and the die is on the die pad. The interconnect includes leads. The semiconductor package includes a mold compound encapsulating a portion of the interconnect, and the leads extend away from the mold compound. The semiconductor package includes an immersion tin layer on a tip of the leads. The immersion tin layer overlays copper of the leads.

### TECHNICAL FIELD

This disclosure relates to semiconductor packages that have leads covered with a layer of tin.

### BACKGROUND

Semiconductor packages (e.g., integrated circuit (IC) packages) are the cornerstone of modern electronics, found in everything from computers and mobile devices to automobiles and industrial machinery. As the demand for smaller, faster and more energy-efficient devices continues to grow, the semiconductor industry is challenged to improve packaging technologies to meet these demands.

Some semiconductor packages are constructed using an interconnect (alternatively referred to as a leadframe) as a support structure, providing mechanical stability, electrical connectivity and heat dissipation for a semiconductor die. The leadframe includes a die pad for mounting the semiconductor die.

A small outline transistor (SOT) package is a type of semiconductor package used in the electronics industry. SOT packages have a compact size and lead configuration that extend from the sides of the package, allowing for surface mounting on printed circuit boards. SOT packages have leads that extends away from the molding compound, which distinguishes them from other package types such as quad flat no-lead (QFN) packages. The design of SOT packages allows for efficient use of space on circuit boards while providing necessary electrical connections and thermal management for the enclosed semiconductor device.

Wettable flanks refer to a specific design feature of the leads in interconnects that are engineered to enhance solderability during an assembly process. The primary purpose of wettable flanks is to ensure robust mechanical and electrical connections by improving the lead's ability to attract and retain solder, thereby creating stronger, more reliable solder joints. This feature helps reduce manufacturing defects such as cold joints or insufficient solder coverage, leading to higher production yields and enhanced performance reliability in semiconductor devices.

### SUMMARY

A first example relates to a semiconductor package including a die with an embedded circuit. The semiconductor package includes an interconnect with a die pad, and the die is on the die pad. The interconnect includes leads. The semiconductor package includes a mold compound encapsulating a portion of the interconnect, and the leads extend away from the mold compound. The semiconductor package includes a matte tin layer on a top surface and a bottom surface of the leads and an immersion tin layer on a tip of the leads. The immersion tin layer overlays copper of the leads.

A second example relates to a circuit including a printed circuit board (PCB) and a semiconductor package mounted on the PCB. The semiconductor package includes a die with an embedded circuit and an interconnect. The interconnect includes a die pad, and the die is on the die pad. The interconnect includes leads and a mold compound encapsulating a portion of the interconnect. The leads extend away from the mold compound. The semiconductor package includes a matte tin layer on a top surface and a bottom surface of the leads and an immersion tin layer on a tip of the leads. The immersion tin layer overlays copper of the leads.

A third example relates to a method of fabricating a semiconductor package. The method includes trimming leads of an interconnect. A portion of the interconnect is encapsulated with a mold compound, the leads of the interconnect extend away from the mold compound, and a top surface and a bottom surface of the leads have a matte tin layer overlaying copper. The method also includes applying an immersion tin layer on a tip of the leads responsive to the trimming.

### BRIEF DESCRIPTION OF THE DRAWINGS

FIG. 1A illustrates an example of a semiconductor package that includes leads coated with matte tin (Sn) and immersion tin (ImSn).

FIG. 1B illustrates a cross-sectional view of the semiconductor package of FIG. 1A.

FIG. 2A illustrates an example of a circuit that implements a semiconductor device mounted on a PCB with leads that have exposed bare copper.

FIG. 2B illustrates a circuit that includes the semiconductor package of FIGS. 1A and 1B mounted on a PCB.

FIGS. 3-10 illustrate stages of a method for fabricating a semiconductor package.

FIG. 11 illustrates a flowchart of an example method for fabricating a semiconductor package.

FIG. 12 illustrates a flowchart of another example method for fabricating a semiconductor package.

### DETAILED DESCRIPTION

This description relates to a semiconductor package, such as a small outline transistor (SOT) package that combines matte tin (Sn) and immersion tin (ImSn) plating processes on leads of the semiconductor package. The semiconductor package could be either a wirebond SOT package or an SOT flipchip package. For wirebond SOT packages, wire bonds connect to copper leads with silver spots printed at the wire bond to lead connection spots. For flipchip SOT packages, dies with solder bumps make direct connections to the copper leads using a reflow process. Matte tin (Sn) plating is performed before a trim process (e.g., trimming of the leads) to cover surfaces of the leads, including at least the top and bottom surfaces of the leads. This trimming exposes bare copper at the tips of the leads. Immersion tin (ImSn) plating is applied in response to the trimming to overlay copper (Cu) on the tips of the leads. The tin coverage, particularly on the tips of the leads enables uniform solder shape formation during surface mount technology (SMT) processes, ensuring proper solder wetting height and allowing customers employing the semiconductor device to monitor soldering performance using automated optical inspection (AOI). The process utilizes existing immersion tin production lines developed for quad flat no-leads (QFN) packages, requiring no additional tooling for SOT packages. This solution addresses the lack of wettable flank options for SOT packages, meeting automotive industry requirements (among other industries) for reliable solder joints and visual inspection capabilities.

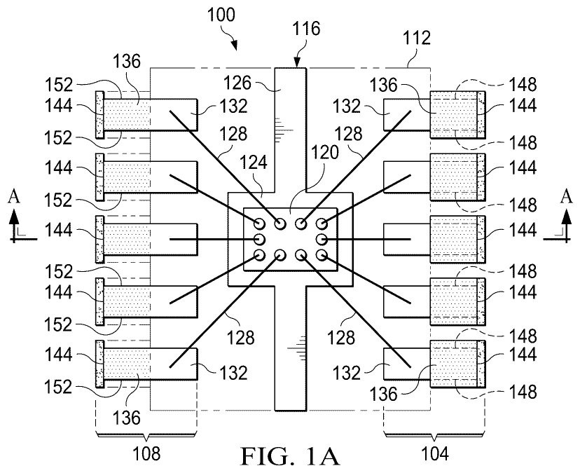

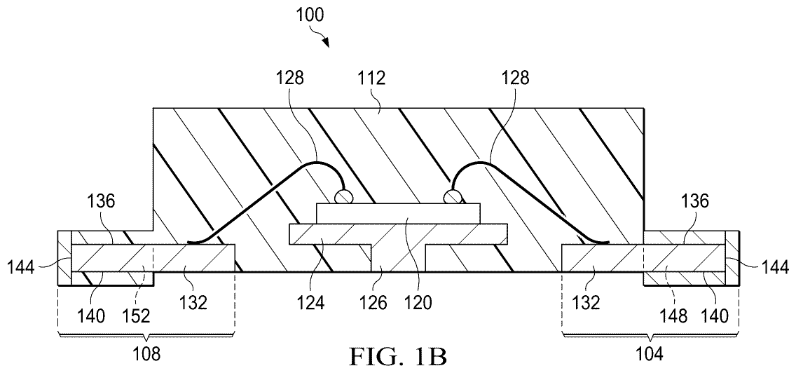

FIG. 1A illustrates an example of a semiconductor package 100 that includes a first set of leads 104 and a second set of leads 108 that extend away from a center region encapsulated in a mold compound 112. FIG. 1B illustrates a cross-sectional view of the semiconductor package 100 taken along line A-A. The semiconductor package 100 could be, for example, an SOT. Moreover, for purposes of illustration, portions of the mold compound 112 are shown as being transparent to reveal embedded features.

The mold compound 112 encapsulates an interconnect 116. In the examples illustrated, the interconnect 116 is a bare copper (Cu) interconnect, such that material such as tin (Sn) is applied to the first set of leads 104 and the second set of leads 108 after the mold compound 112 is applied to encapsulate a portion of the interconnect 116. A die 120 mounted on a die pad 124 of the interconnect 116. The die pad 124 includes a ground plane 126 that extends along an axis of the semiconductor package 100. The die 120 includes an embedded circuit. For wirebond SOT packages, wire bonds 128 couple the die 120 to the first set of leads 104 and the second set of leads 108. For flipchip SOT packages, dies with solder bumps make direct connections to the copper leads using a reflow process.

The first set of leads 104 and the second set of leads 108 include a region 132 embedded in the mold compound 112 (only some of which are labeled). In the example illustrated, these regions 132 are composed of bare copper (Cu), but in other examples, these regions 132 can be pre-plated with a layer material composed of gold (Au). A top surface 136 and a bottom surface 140 (visible in FIG. 1B) of leads in both the first set of leads 104 and the second set of leads 108 are covered with a layer of matte tin (Sn). The matte Sn layer on the top surface 136 and the bottom surface 140 of the leads in the first set of leads 104 and the second set of leads 108 has a thickness of about 7 micrometers (μm) to about 20 μm. The thickness of at least about 7 μm for the matt Sn layer is needed to curtail risk of whiskers and to ensue component solderability over an intended shelf life (e.g., 10 years) of the semiconductor package 100. Additionally, a thickness greater than about 20 μm for the matte Sn layer can peel or slough off. Accordingly, to ensure the needed shelf life and to avoid such peeling and/or sloughing off, the matte Sn layer has a thickness of about 7 μm to about 20 μm. The matte Sn is applied with an electroplating operation. In examples where the interconnect 116 is pre-plated, the top surface 136 and the bottom surface 140 (at least) of the leads in the first set of leads 104 and the second set of leads 108 have a layer of gold (Au) (e.g., a gold layer).

Leads of the first set of leads 104 and the second set of leads 108 have tips 144 with regions having a layer of immersion tin (ImSn) overlaying copper (Cu) of the leads. ImSn is formed from dipping the semiconductor package 100 into a solution that is a mixture of tin ions (Sn²⁺), thiourea, methanesulfonic acid (MSA), citric acid and additive silver (Ag²⁺) to cause a replacement reaction between exposed copper on the tips 144 of the leads in the first set of leads 104 and the second set of leads 108 to form a ImSn layer composed of tin (Sn) and about 1% silver (Ag). More particularly, the leads of the first set of leads 104 and the second set of leads 108 have pure tin (Sn) or nearly pure tin (Sn) on an outer region of the tips 144 and Cu₆Sn₅ as an intermetallic compound (IMC) on the underneath region of the tips 144. Additionally, the tips 144 can also have a small amount of silver (Ag) situated on a grain boundary of the tin (Sn). This addition of silver (Ag) reduces a propensity for whisker growth on the tips 144. The ImSn on the tips 144 of the leads in the first set of leads 104 and the second set of leads 108 has a thickness of about 2.6 μm to about 3.5 μm. The thickness of the ImSn is at least 2.6 μm to ensure that the semiconductor 100 meets an intended shelf life (e.g., 10 years) before the Sn is consumed by copper (Cu) at the tips 144 (generating a Cu-Cn IMC, which is un-solderable). Further, the thickness of about 3.5 μm is a maximum thickness of the immersion Sn process, as almost no chemical displacement reactions happen beyond 3.5 μm. Thus, the tips 144 of leads of the first set of leads 104 and the second set of leads 108 has a thickness of about 2.6 μm to about 3.5 μm. In some examples, the layer of the ImSn has a different thickness than the layer of the matte Sn. Moreover, in appearance, the ImSn is darker than the matte Sn.

In the example illustrated, sidewalls 148 of the leads in the first set of leads 104 are also coated with matte Sn. In contrast the leads in the second set of leads 108 have sidewalls 152 that are covered (or partially covered) by a flash of the mold compound 112 that expanded during encapsulation of the semiconductor package 100. Although in the illustrated example, all of the leads coated with the mold compound 112 are in the second set of leads 108, in other examples some (or all) of the leads covered in mold compound 112 can be included in the first set of leads 104. That is, in many examples, both the first set of leads 104 and the second set of leads 108 includes leads coated with the mold compound 112 and leads that are not coated with the mold compound 112.

The combination of matte tin and immersion tin plating on the semiconductor package 100 provides improved tin coverage on the leads of the semiconductor package 100, including the leads in the first set of leads 104 and the second set of leads 108. This improved tin coverage enables generation of an intermetallic compound (IMC) layer between the leads of the semiconductor package 100 and a solder joint, enabling uniform soldering shape formation during surface mount technology (SMT) processes where the semiconductor package 100 is mounted on a printed circuit board (PCB). The uniform solder shape ensures proper solder wetting height and allows customers that employ the semiconductor package 100 to monitor soldering performance using automated optical inspection (AOI). The semiconductor package 100 demonstrates reliability in various tests such as solderability, board level reliability (BLR), and whisker tests.

The semiconductor package 100 is suitable for various electronic applications, particularly in the automotive industry where high reliability and visual inspection capabilities are needed. The improved soldering performance and ability to form uniform solder fillets (or one or more solder joints having a solder fillet) make the semiconductor package 100 appropriate for use in automotive electronics, consumer electronics and other applications that need robust and reliable semiconductor components. The enhanced wettability and visual inspection capabilities also make the semiconductor package 100 employable in high-volume manufacturing environments where automated optical inspection is commonly used for quality control.

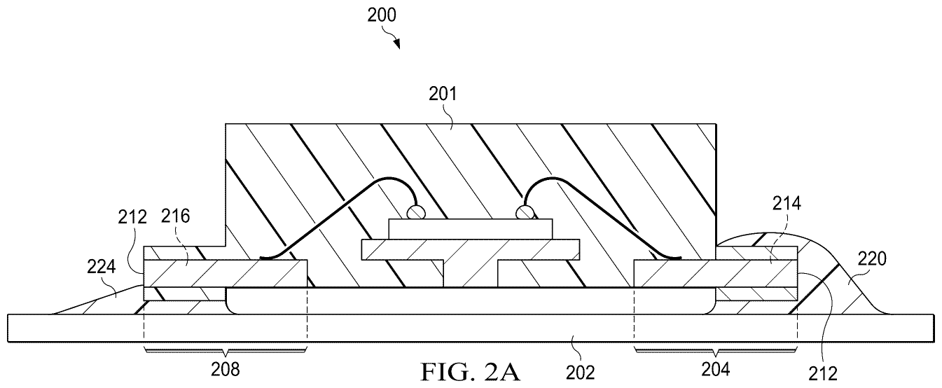

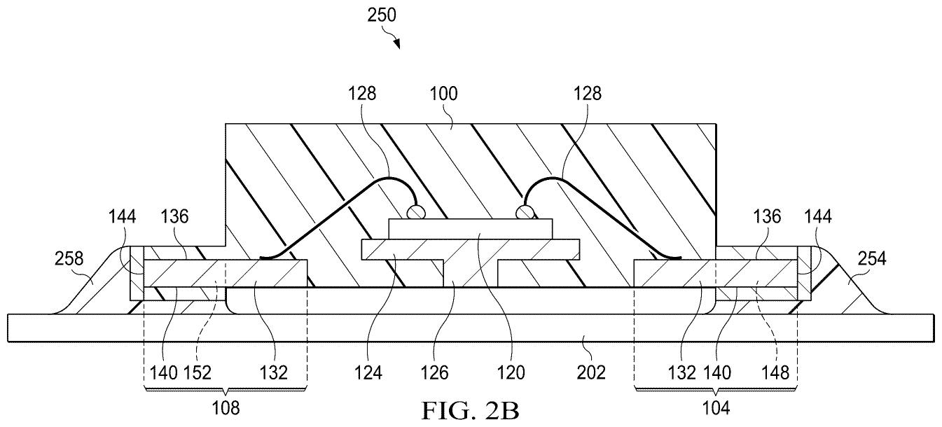

FIG. 2A illustrates an example of a circuit 200 that implements a semiconductor device 201 mounted on a PCB 202 (e.g., using an SMT process). The semiconductor device 201 does not have ImSn, and is limited to including matte Sn. More specifically, the semiconductor device 201 includes a first lead 204 and a second lead 208 that each have exposed copper (Cu) on tips 212. Moreover, the first lead 204 has a layer matte Sn plating a sidewall 214, and the second lead 208 has mold flash covering a portion of the sidewall 216. The exposed copper (Cu) on the tips 212 (on the first lead 204 and the second lead 208) and sidewalls 216 (on the second lead 208) can lead to poor solder joint formation and reliability issues.

The first lead 204 is soldered to the PCB 202 with a first solder joint 220. Because the tip 212 is exposed copper (Cu) and because the sidewall 216 is covered by matte Sn, which easily allows solder to climb on to the sidewall 216 and onto the top surface 136 of the first set of leads 104, an excessive amount of solder is needed to adequately adhere the first lead 204 to the PCB 202. This excessive amount of solder forming the first solder joint 220 can lead to bridging with other circuit components (not shown) which can impact performance of the circuit 200 implementing the first solder joint 220. Conversely, the second lead 208 is coupled to the PCB 202 with a second solder joint 224. In the second solder joint 224, because the tip 212 of the second lead 208 has exposed copper and the sidewall 216 is coated with mold flash, there is a poor connection between the tip 212 and the sidewall 216 of the second lead 208 and the solder forming the second solder joint 224. This poor connection results in voids forming between the second lead 208 and the solder of the second solder joint 224. Additionally, the second solder joint 224 is prone to cracking. These limitations (poor surface area and cracking) can impact performance of the semiconductor device 201. The lack of uniform tin (Sn) coverage on the leads makes it difficult to monitor soldering performance using automated optical inspection (AOI) techniques, which is often leveraged in automotive applications.

FIG. 2B illustrates a circuit 250 that includes the semiconductor package 100 of FIGS. 1A and 1B mounted on the PCB 202. The semiconductor package 100 includes leads in the first set of leads 104 and the second set of leads 108 that have tips 144 with a layer of ImSn overlaying copper in the tips of the leads. Moreover, the leads in the first set of leads 104 and the second set of leads 108 have a layer of matte Sn on the top surface 136 and the bottom surface 140. Further, in the example illustrated, the leads in the first set of leads 104 have sidewalls 148 with a layer of the matte Sn coated thereon. The matte Sn layer has a thickness of about 7 μm to about 20 μm (e.g., to meet an intended shelf life of 10 years and to avoid peeling and/or sloughing off of the matte Sn layer), and the ImSn layer has a thickness of about 2.6 to 3.5 μm (e.g., to meet the intended shelf life of 10 years and without exceeding the maximum thickness of the immersion Sn process), such that these layers can have different thicknesses in some examples. This combination of matte Sn and ImSn plating provides improved tin (Sn) coverage on the SOT leads, addressing the limitations seen in the semiconductor device 201 of FIG. 2A.

The leads in the first set of leads 104 are coupled to the PCB 202 with a solder joint 254 that has a uniform solder fillet shape. Similarly, the leads in the second set of leads 108 are coupled to the PCB 202 with a solder joint 258 that also has a uniform solder fillet. The uniform solder fillet shape is achieved due to the ImSn layer on the tips 144, which promotes better wetting and solder joint formation. Moreover, solder in the solder joint 254 and the solder joint 258 adheres to the ImSn on the tips 144 of the leads of the first set of leads 104 and the second set of leads 108 to improve reliability of the connection between the semiconductor package 100 and the PCB 202. The ImSn layer forms an intermetallic compound (IMC) layer between the leads of the first set of leads 104 and the second set of leads 108 and the solder joints 254 and 258, further enhancing the connection strength and reliability. The improved adherence of the solder joint 254 and the solder joint 258 enables the circuit 250 to be deployed in automotive applications (e.g., installed in an automobile). Moreover, while the best results can be expected when there is no mold flash on the side surfaces of the solder joints 254 and 258, improved adherence of the solder joints 254 and 258 will occur even when residual mold flash remains on a portion of the side surface or side surfaces of any one or more of the solder joints 254 and 258 as the resulting solder joints 254 and 258 will yet cover at least the bottom and tip surfaces and any portions of the side surfaces of solder joints 254 and 258. The circuit 200 of FIG. 2A may not be deployable in automotive applications due to the exposed copper on the tips 212 of the first lead 204 and the second lead 208. In contrast, the improved tin (Sn) coverage on the semiconductor package 100 (e.g., an SOT) for the circuit 250 of FIG. 2B leads allows customers that employ the circuit 250 to build criteria to monitor soldering performance by AOI, meeting the wettable flank specifications for automotive applications.

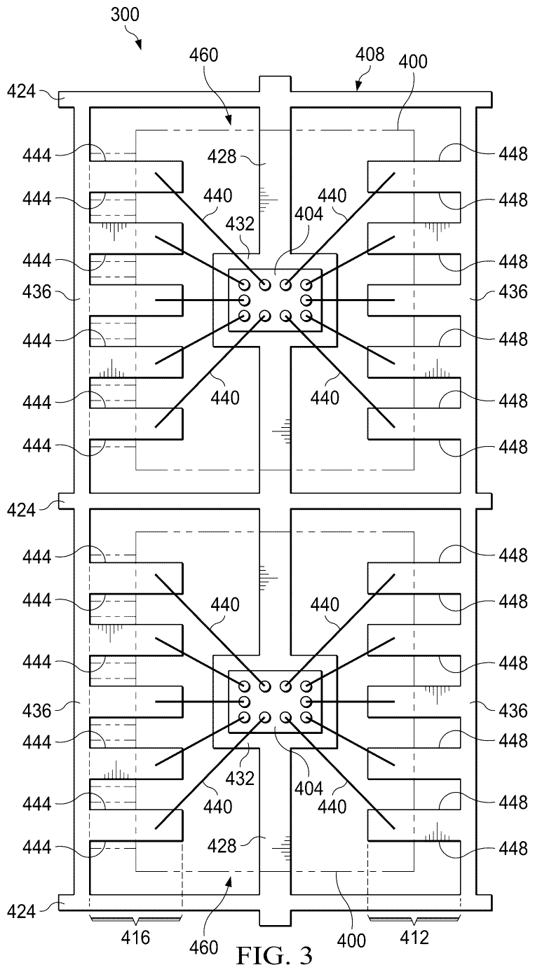

FIGS. 3-10 illustrate stages of a method for fabricating a semiconductor package, such as the semiconductor package 100 of FIGS. 1A and 1B. The method of FIGS. 3-10 illustrates how ImSn (immersion tin) is applied to leads of the semiconductor package (e.g., an SOT semiconductor package).

As illustrated in FIG. 3 in a first stage 300 of the method, a mold compound 400 encapsulates dies 404 and portions of an interconnect 408. The interconnect 408 (in the current state) supports the fabrication of an array of semiconductor packages. The interconnect 408 in the present example is an exposed bare copper interconnect. The interconnect 408 includes a first set of leads 412 and a second set of leads 416 that extend away from the mold compound 400 and the dies 404. A portion of the leads of the first set of leads 412 and the second set of leads 416 are encapsulated by the mold compound 400, and a portion are exposed. The mold compound 400 is shown as being transparent in certain regions to improve visualization. The interconnect 408 also includes cross-bars 424 coupled to the first set of leads 412, the second set of leads 416, ground planes 428 and die pads 432. The dies 404 are mounted on the die pads 432. Lead cross bars 436 of the interconnect 408 are coupled to the leads of the first set of leads 412 and the second set of leads 416 and to the cross-bars 424.

In the example illustrated in FIGS. 3-10, the dies 404 are coupled to the leads of the first set of leads 412 and the second set of leads 416 with wire bonds 440 (only some of which are labeled). However, in other examples, the interconnect 408 and the dies 404 can be coupled to the leads of the first set of leads 412 and the second set of leads 416 with flipchip techniques. In the example illustrated, sidewalls 444 of the leads in the second set of leads 416 have mold compound 400 flashes. In contrast, the sidewalls 448 of the first set of leads 412 have a layer of matte Sn plated thereon.

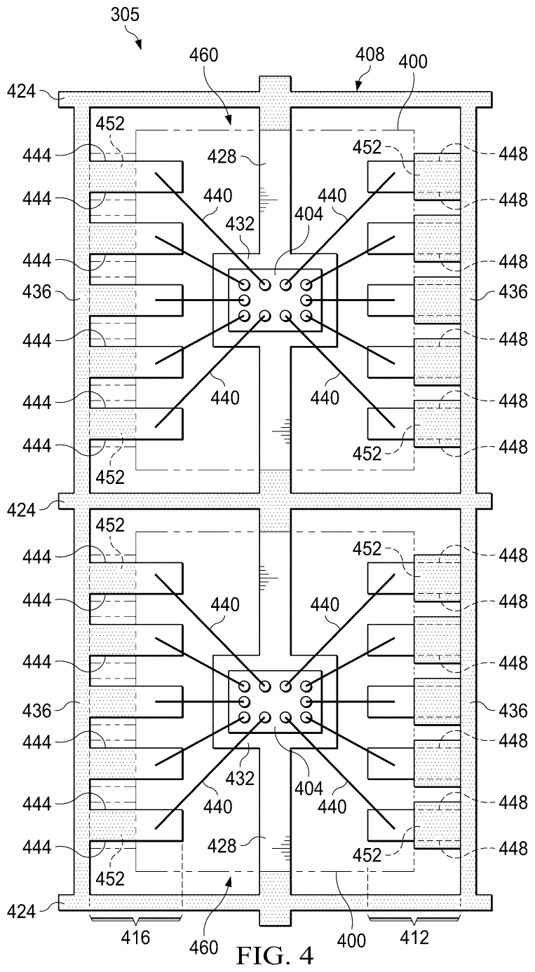

As illustrated in FIG. 4, in a second stage 305 of the method, a layer of matte Sn (matte tin) is applied to the exposed portions of the interconnect 408. The matte Sn is applied with an electroplating technique. In this manner, a top surface 452 (only some of which are labeled) and a bottom surface (hidden from view) of the leads in the first set of leads 412 and the second set of leads 416 are coated with the layer of matte Sn. The matte Sn has a thickness of about 7 to about 20 μm (e.g., to meet an intended shelf life of 10 years and to avoid peeling and/or sloughing off of the matte Sn layer). In some examples, the interconnect 408 can be pre-plated with a layer of gold (Au), which can be referred to as a gold layer.

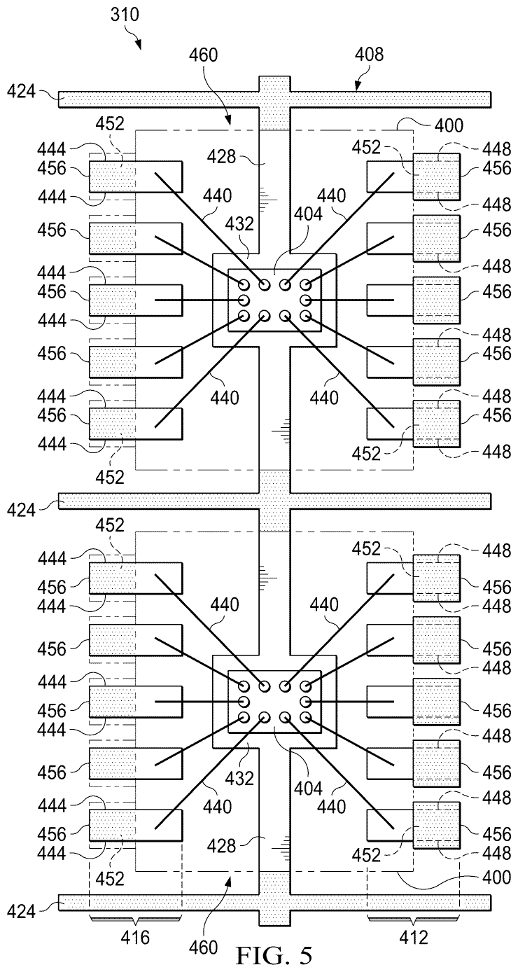

As illustrated in FIG. 5, in a third stage 310 of the method, the leads of the first set of leads 412 and the second set of leads 416 are trimmed to form an array of semiconductor packages 460. Trimming includes cutting (e.g., with a saw or a laser) the lead cross bars 436 and a portion of the cross-bars 424. As a result of the trimming, tips 456 of the leads in the first set of leads 412 and the second set of leads 416 have exposed bare copper.

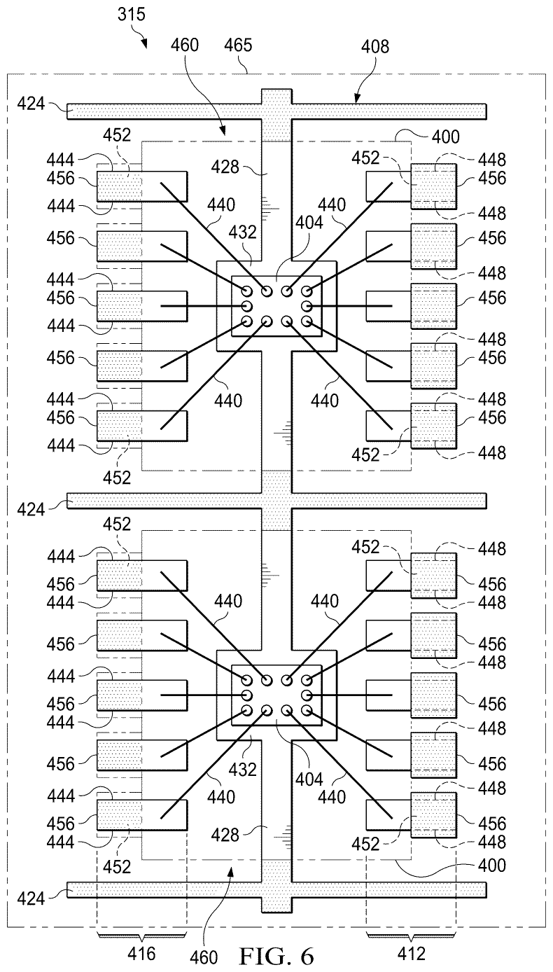

As illustrated in FIG. 6, in a fourth stage 315, a tape 465 is adhered to a bottom surface of the array of semiconductor packages 460. More specifically, the tape 465 is adhered to the mold compound 400 of the array of semiconductor packages 460.

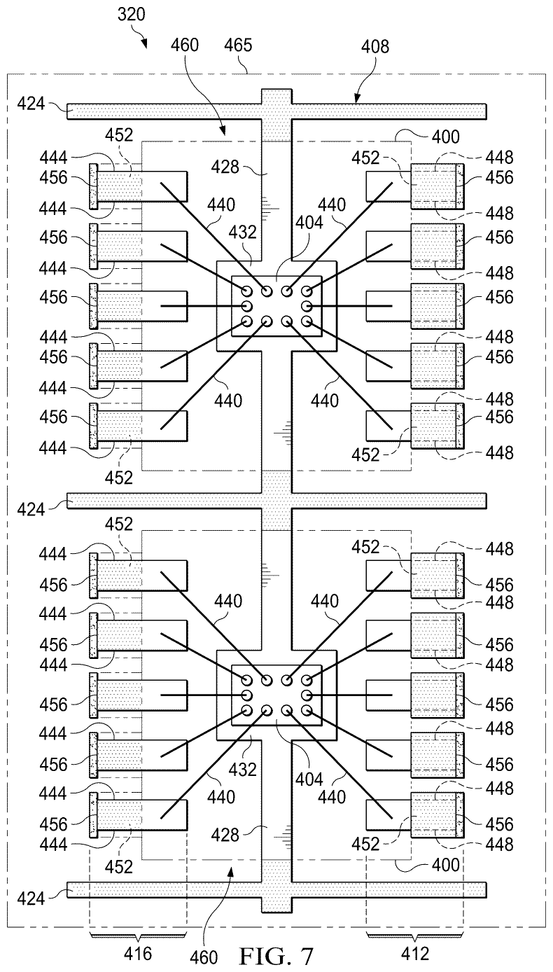

As illustrated in FIG. 7, in a fifth stage 320 of the method, a layer of ImSn (immersion tin) is applied to exposed bare copper of the interconnect 408. The application of the ImSn includes a tin plating process where the array of semiconductor packages 460 are dipped in a solution that has a mixture of Tin ions (Sn²⁺), thiourea, MSA, citric acid and additive silver (Ag²⁺) to cause a replacement reaction between exposed copper on the tips 456 of the leads in the first set of leads 412 and the second set of leads 416 to form a ImSn layer composed of tin (Sn) and about 1% silver (Ag). More particularly, the leads of the first set of leads 412 and the second set of leads 416 pure have pure tin (Sn) or nearly pure tin (Sn) on an outer (top) region of the tips 456 and Cu₆Sn₅ as an IMC on an underneath region of the tips 456. Additionally, the tips 456 can also have a small amount of silver (Ag) situated on a grain boundary of the tin (Sn). This addition of silver (Ag) reduces a propensity for whisker growth on the tips 456. The ImSn has a darker tint than the matte Sn. In the example illustrated, a layer of the ImSn is formed on tips 456 of the leads in the first set of leads 412. Similarly, a layer of the ImSn is formed on the tips 456 of the leads in the second set of leads 416. The ImSn has a thickness of about 2.6 to about 3.5 μm (e.g., to meet the intended shelf life of 10 years and without exceeding the maximum thickness of the immersion Sn process), such that the ImSn and the matte Sn have different thicknesses in some examples.

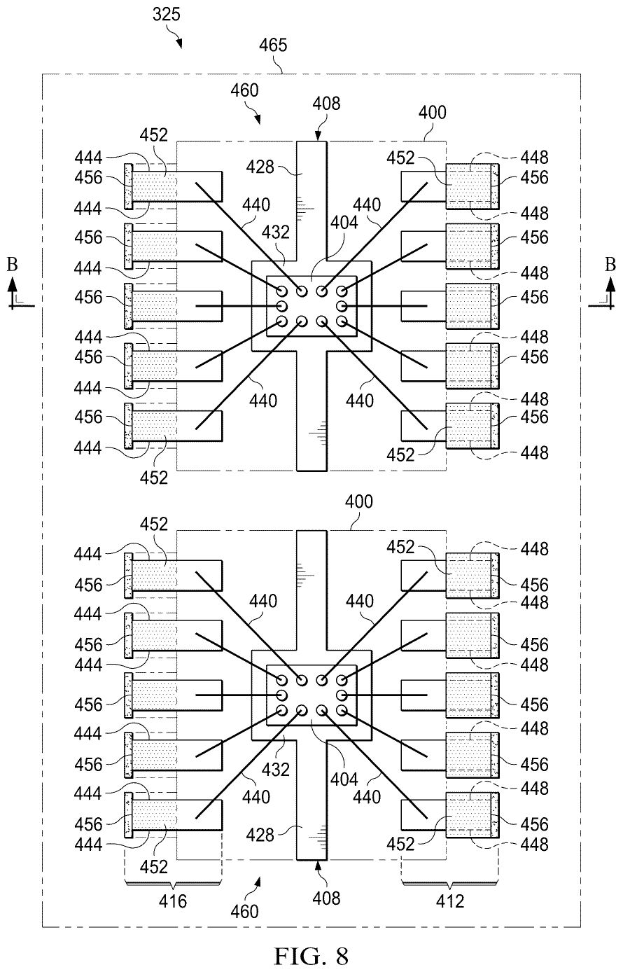

As illustrated in FIG. 8, in a sixth stage 325 of the method, the cross-bars 424 are sawed (e.g., by a diamond saw, a laser saw, a plasma saw, etc.) in a singulation operation of the array of semiconductor packages 460. In this manner, the individual semiconductor packages 460 are galvanically isolated.

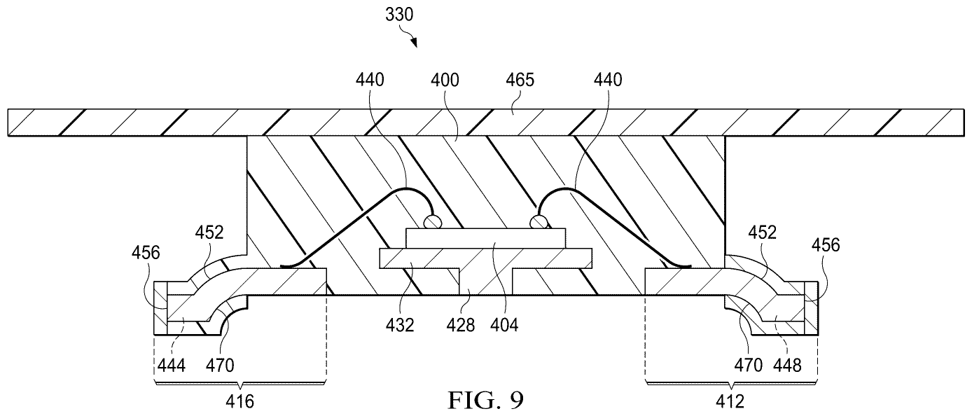

As illustrated in FIG. 9, in a seventh stage 330 of the method, leads of the array of semiconductor packages 460 are bent in a forming operation. FIG. 9 illustrates a cross-sectional view of the semiconductor packages 460 of FIG. 8 taken along line B-B. In FIG. 9, a bottom surface 470 of the leads of the first set of leads 412 and the second set of leads 416 is visible, and coated with a layer of matte Sn. Forming of the leads enables the resultant semiconductor packages 460 to have shaped leads. Moreover, in some examples, the forming operation can be omitted.

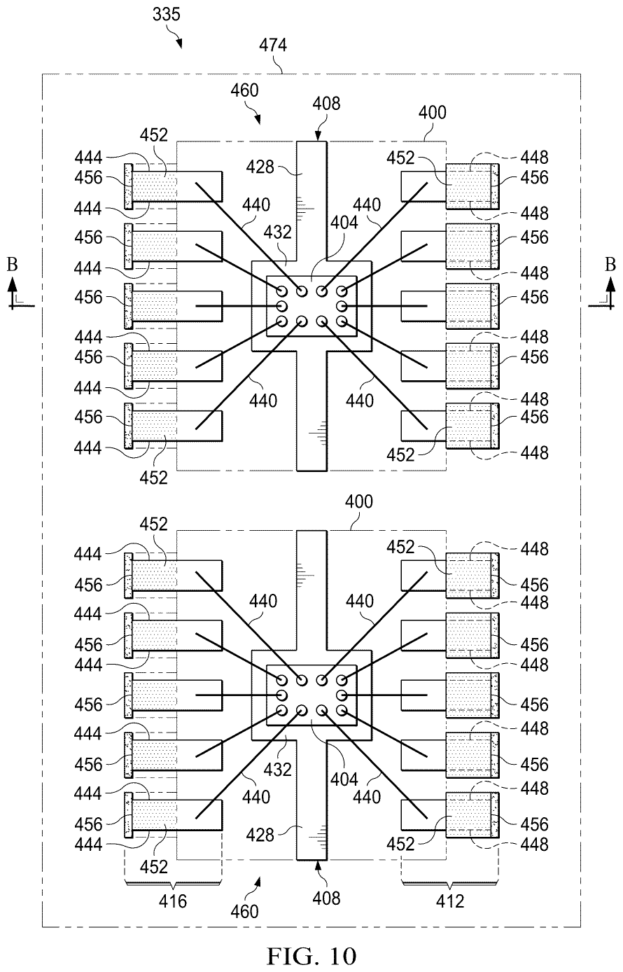

As illustrated in FIG. 10, in an eighth stage 335 of the method, the tape 465 (e.g., a first tape) is removed and the semiconductor packages 460 are attached (adhered) to a second tape 474 in a tape and reel operation. The semiconductor packages 460 are reeled for delivery for installation of the semiconductor packages 460 into various circuits, including automotive applications.

The method described with respect to FIGS. 3-10 provides an innovative approach for fabricating the semiconductor packages 460 with improved lead plating. This method combines matte Sn and ImSn plating to improve tin coverage on leads of the semiconductor packages 460 (e.g., SOT semiconductor packages). This comprehensive method results in semiconductor packages 460 with enhanced solderability, enabling uniform solder fillet formation and improved reliability. The combination of matte Sn and ImSn plating enables better wetting during surface mount technology processes and allows for effective AOI in automotive applications and/or other applications. This method addresses key challenges in SOT package manufacturing, particularly for high-reliability automotive electronics by providing a wettable flank solution that meets industry specifications for reliable solder joints and visual inspection capabilities.

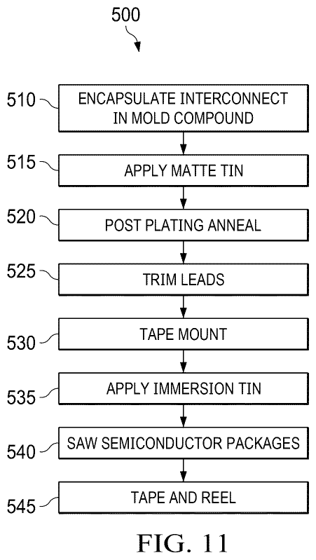

FIG. 11 illustrates a flowchart of an example method 500 for fabricating a semiconductor package, such as the semiconductor package 100 of FIGS. 1A and 1B. At block 510, an interconnect (e.g., the interconnect 116 of FIGS. 1A and 1B) with dies (e.g., a plurality of the dies 120 of FIGS. 1A and 1B) mounted thereon is encapsulated in a mold compound (e.g., the mold compound 400 of FIG. 3).

At block 515, a layer of matte Sn is applied (e.g., in an electroplating process) to exposed portions of the interconnect, including a top surface and a bottom surface of leads extending from the mold compound. The matte Sn layer has a thickness of about 7 to about 20 μm (e.g., to meet an intended shelf life of 10 years and to avoid peeling and/or sloughing off of the matte Sn layer). At block 520, a post-plating anneal (e.g., heating) is executed to improve adhesion and properties of the matte tin layer. At block 525, the leads of the interconnect are trimmed to cut off (detach) the leads from lead cross bars (e.g., the lead cross bars 436 of FIG. 3), exposing bare copper on the lead tips. At block 530, the semiconductor packages are mounted on tape (e.g., a first tape) for subsequent processing.

At block 535, a layer of ImSn is applied to the exposed bare copper surfaces, including the lead tips. The ImSn layer has a thickness of about 2.6 to about 3.5 μm (e.g., to meet the intended shelf life of 10 years and without exceeding the maximum thickness of the immersion Sn process) and forms an intermetallic compound with the copper. At block 540, the semiconductor packages are singulated by sawing. At block 545, the singulated semiconductor packages are prepared for delivery through a tape and reel operation (e.g. attaching the semiconductor packages to a second tape, such as the second tape 474 of FIG. 10). The method 500 combines matte Sn and ImSn plating to achieve improved tin coverage on SOT package leads, addressing key challenges in SOT package manufacturing for high-reliability automotive electronics.

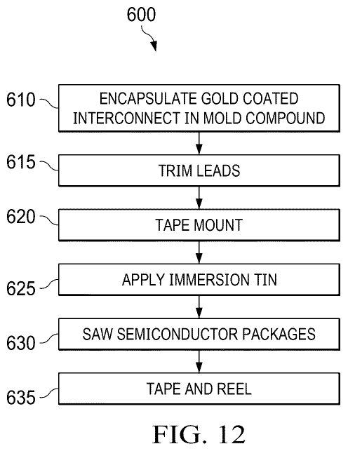

FIG. 12 illustrates a flowchart of an example method 600 for forming a semiconductor package, such as the semiconductor package 100 of FIGS. 1A and 1B. At block 610, an interconnect (e.g., the interconnect 116 of FIGS. 1A and 1B) with dies (e.g., a plurality of the die 120 of FIGS. 1A and 1B) mounted thereon is encapsulated in a mold compound (e.g., the mold compound 400 of FIG. 3). In the method 600, the interconnect comes with pre-plated with a layer of gold (Au) such that the application of matte Sn can be omitted.

At block 615, the leads of the interconnect are trimmed to cut off (detach) leads from lead cross bars (e.g., the lead cross bars 436 of FIG. 3) exposing bare copper on the lead tips. At block 620, the semiconductor packages are mounted on tape (e.g., tape 465 of FIG. 7) for subsequent processing. At block 625, a layer of ImSn is applied to the exposed bare copper surfaces, including the lead tips. The ImSn layer has a thickness of about 2.6 μm to about 3.5 μm (e.g., to meet the intended shelf life of 10 years and without exceeding the maximum thickness of the immersion Sn process) and forms an intermetallic compound with the copper. At block 630, the semiconductor packages are singulated by sawing. At block 635, the singulated semiconductor packages are prepared for delivery through a tape and reel operation (e.g. using a second tape, such as the second tape 474 of FIG. 10). The method 600 combines pre-plated gold (Au) and ImSn plating to achieve coverage (coating) on semiconductor packages (e.g., SOT packages), addressing challenges in SOT package manufacturing for high-reliability automotive electronics.

In this description, unless otherwise stated, “about,” preceding a parameter means being within +/−10 percent of that parameter. Modifications are possible in the described embodiments, and other embodiments are possible, within the scope of the claims.

What is claimed is:

1. A semiconductor package comprising:
a die with an embedded circuit;
an interconnect comprising:
a die pad, wherein the die is on the die pad; and
leads;
a mold compound encapsulating a portion of the interconnect, and the leads extend away from the mold compound;
an immersion tin layer on a tip of the leads, wherein the immersion tin layer overlays copper of the leads.

2. The semiconductor package of claim 1 further comprising a matte tin layer or a gold layer on a top surface and a bottom surface of the leads.

3. The semiconductor package of claim 2, wherein the matte tin layer or the gold layer overlays sidewalls of the leads.

4. The semiconductor package of claim 3, wherein mold flashes of the mold compound overlay a portion of sidewalls of the leads.

5. The semiconductor package of claim 1, wherein the semiconductor package is a small outline transistor (SOT) package.

6. The semiconductor package of claim 1, wherein the immersion tin layer has a thickness between 2.6 and 3.5 micrometers.

7. The semiconductor package of claim 1, wherein the semiconductor package is mounted on a printed circuit board (PCB).

8. The semiconductor package of claim 7, wherein the immersion tin layer forms an intermetallic compound (IMC) layer between the leads and solder joints connecting the semiconductor package to the PCB.

9. A circuit comprising:
a printed circuit board (PCB); and
a semiconductor package mounted on the PCB, the semiconductor package comprising:
a die with an embedded circuit;
an interconnect comprising:
a die pad, wherein the die is on the die pad; and
leads;
a mold compound encapsulating a portion of the interconnect, and the leads extend away from the mold compound;
an immersion tin layer on a tip of the leads, wherein the immersion tin layer overlays copper of the leads.

10. The circuit of claim 9, wherein the semiconductor package further comprises a matte tin layer or a gold layer on a top surface and a bottom surface of the leads.

11. The circuit of claim 10, wherein the matte tin layer or the gold layer and the immersion tin layer have different thicknesses.

12. The circuit of claim 9, wherein the immersion tin layer has a thickness between 2.6 and 3.5 micrometers.

13. The circuit of claim 9, wherein the immersion tin layer forms an intermetallic compound (IMC) layer between the leads and solder joints connecting the semiconductor package to the PCB.

14. The circuit of claim 13, wherein one or more of the solder joints form solder fillet.

15. The circuit of claim 9, wherein the circuit is installed in an automobile.

16. A method of fabricating a semiconductor package, comprising:
trimming leads of an interconnect, wherein a portion of the interconnect is encapsulated with a mold compound, the leads of the interconnect extend away from the mold compound, and a top surface and a bottom surface of the leads have a matte tin layer or a gold layer overlaying copper; and
applying an immersion tin layer on a tip of the leads responsive to the trimming.

17. The method of claim 16, wherein the a top surface and a bottom surface of the leads have a matte tin layer, the method further comprising:
applying the matte tin layer on the top surface and the bottom surface of the leads, wherein the interconnect is a bare copper interconnect.

18. The method of claim 16, further comprising forming the leads responsive to the applying of the immersion tin layer.

19. The method of claim 16, further comprising:
sawing the interconnect encapsulated in the mold compound responsive to the applying of the immersion tin layer to form semiconductor packages.

20. The method of claim 19, further comprising, attaching the semiconductor packages to tape.
